(19) United States
(12) Patent Application Publication
(10) Pub. No.: US 2023/0274040 A1
(43) Pub. Date: Aug. 31, 2023

(54) MODELING SHAPES USING DIFFERENTIABLE SIGNED DISTANCE FUNCTIONS

(71) Applicant: Adobe Inc., San Jose, CA (US)

(72) Inventors: Adrien Kaiser, Paris (FR); Vojtech Krs, San Jose, CA (US); Thibault Groueix, Grenoble (FR); Tamy Boubekeur, Paris (FR); Pierre Gueth, Lyon (FR); Mathieu Gaillard, West Lafayette, IN (US); Matheus Gadelha, Amherst, MA (US)

(21) Appl. No.: 17/683,188

(22) Filed: Feb. 28, 2022

(51) Int. Cl. G06F 30/12; G06T 19/20

(52) U.S. Cl. CPC G06F 30/12; G06T 19/20; G06T 2219/2021

(57) ABSTRACT

Certain aspects and features of this disclosure relate to modeling shapes using differentiable, signed distance functions. 3D modeling software can edit a 3D model represented using the differentiable, signed distance functions while displaying the model in a manner that is computing resource efficient and fast. Further, such 3D modeling software can automatically create such an editable 3D model from a reference representation that can be obtained in various ways and stored in a variety of formats. For example, a real-world object can be scanned using LiDAR and a reference representation can be produced from the LiDAR data. Candidate procedural models from a library of curated procedural models are optimized to obtain the best procedural model for editing. A selected procedural model provides an editable, reconstructed shape based on the reference representation of the object.

### TECHNICAL FIELD

The present disclosure generally relates to three-dimensional (3D) computer modeling. More specifically, but not by way of limitation, the present disclosure relates to techniques for efficiently rendering an editable, reconstructed, 3D model of an object based on a reference representation of a similar object.

### BACKGROUND

3D modeling software applications are used in a number of different fields. For example, such applications may be used to create models of actual objects to be manufactured. The models can in turn be used to produce production drawings or computer files to control manufacturing equipment. 3D modeling software may also be used to create realistic 3D shapes of products for marketing purposes. 3D modeling may also be employed to render realistic objects for placement in images for video games, television programs, movies, training simulators, or virtual reality attractions at amusement parks. These objects can be part of an entire virtual scene or can be added to a captured image during post production.

### SUMMARY

Certain aspects and features of the present disclosure relate to modeling shapes using differentiable, signed distance functions. For example, a computer-implemented method involves accessing a reference representation of an object and transforming the reference representation into a common representation by sampling points associated with the reference representation. The computer-implemented method further involves selecting candidate procedural models corresponding to the reference representation based on the common representation, and optimizing each of the candidate procedural models by comparing a procedural value and a reference value of a differentiable signed distance function for each of the points associated with the reference representation to provide a selected procedural model. The computer-implemented method also involves producing a 3D, editable procedural model of a reconstructed shape based on the reference representation of the object using the selected procedural model.

Other embodiments of this aspect include corresponding computer systems, apparatus, and computer programs recorded on one or more computer storage devices, each configured to perform the actions of the methods.

This summary is not intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim.

### BRIEF DESCRIPTION OF THE DRAWINGS

Features, embodiments, and advantages of the present disclosure are better understood when the following Detailed Description is read with reference to the accompanying drawings, where:

FIG. 1 is a diagram showing an example of a computing environment for modeling shapes using differentiable, signed distance functions, according to certain embodiments.

FIG. 2 is an example of reference representation and a corresponding rendered, 3D model image produced by modeling a shape using differentiable, signed distance functions, according to certain embodiments.

FIG. 3 is a flowchart of an example of a process for modeling shapes using differentiable, signed distance functions, according to some embodiments.

FIG. 4 is an example of a reference representation of a shape that can be used for modeling the shape using differentiable, signed distance functions, according to some embodiments.

FIG. 5 is an example of images depicting an optimization process including a candidate procedural model with parameters being varied to select a procedural model as part of modeling a shape using differentiable, signed distance functions, according to some embodiments.

FIG. 6 in an example of a result of the optimization showing how a selected procedural model fits a reference object when modeling a shape using differentiable, signed distance functions, according to some embodiments.

FIG. 7 is a flowchart of another example of a process for modeling shapes using differentiable, signed distance functions, according to some embodiments.

FIG. 8 is a diagram of an example of a computing system that can implement aspects of modeling shapes using differentiable, signed distance functions, according to certain embodiments.

### DETAILED DESCRIPTION

3D modeling software applications are used for creating, manipulating, and editing 3D graphical models. 3D modeling software represents models by storing a representation of the shape of a modeled object. For example, some software uses meshes that are combinatorial representations, resulting in high computer storage requirements and an editing process that is slow and computationally expensive. Sometimes a previously created 3D model in this format can be used as a starting point in order to expedite the process, but workflow efficiency can only be gained if the previously created model is similar to the desired result, and such a previously created model may not be available. Once a model is edited, a model file can be exported in a more storage efficient format for use, but many such formats are not editable.

In addition to being resource intensive, existing 3D modeling applications require extensive manual adjustment of modeling parameters to make changes. A high degree of expertise is required to adjust modeling parameters appropriately and efficiently to achieve desired results. Extensive trial and error is often required because many of the modeling parameters interact with each other. These problems are magnified when an entire object must be created from scratch, for example, when there is no similar, previously created model available in an editable format.

Aspects and features of the present disclosure provide 3D modeling software that can be used to edit 3D models represented using differentiable, signed distance functions to maintain editability while displaying changes in a manner that is computing resource efficient and fast. Further, such an application can automatically create such an editable 3D model as a starting point using a reference representation that can be readily obtained and stored in a variety of formats. The reference representation can be obtained, as an example, by scanning a physical object using the light detection and ranging (LiDAR) feature of a mobile device.

The reference representation is transformed into a common representation by sampling points associated with the reference representation. Candidate procedural models corresponding to the reference representation are automatically selected. A procedural model is a collection of efficient algorithms that can generate a specific 3D representation of an object very quickly. The procedural model can be parameterized by input parameters. Changing the input parameters allows the procedural model to generate a variety of similar 3D representations. Each candidate procedural model is automatically optimized by comparing a procedural value and a reference value of a differentiable, signed distance function (SDF) for each of the points associated with the reference representation in order to automatically select one of the candidate models. A 3D, editable procedural model of a reconstructed shape is automatically provided using the selected procedural model. The 3D, editable procedural model approximates the reference representation of the object and can be used as is. Additionally, the use of differentiable, SDFs provides a representation that can be efficiently and easily edited using clear, understandable parameters for design details to produce a desired 3D model.

For example, a LiDAR scanner can create a reference representation from an actual physical object that is similar to the desired model. Alternatively, a reference representation of a similar object can be obtained from a library of stock 3D representations of common objects. The reference representation can be accessed by a 3D modeling software application. When the 3D model editing process is initiated, the software application loads the reference representation and searches candidate procedural models obtained from a library of curated procedural models. The application then optimizes each selected candidate procedural model in order to automatically select one of the candidate procedural models on which a realistic, editable starting 3D model can be based in order to most closely approximate the reference representation. For example, if the reference representation is of a sofa, the realistic, editable 3D model will resemble that sofa. This editable 3D model serves as a starting point for the creation of a desired 3D model, for example, a model of a sofa that has a different appearance. The 3D model of the sofa can be used as is, or alternatively can be easily and quickly changed in shape, surface texture, design details, etc.

In some examples, the 3D modeling software application selects candidate models by using the initial parameters of a procedural graph for a candidate procedural model and generating a 3D, reconstructed shape for each set of parameters. The procedural graphs for the 3D, reconstructed shapes closest to the reference representation are stored and used to optimize each corresponding candidate procedural model. The reconstructed shapes closest to the reference representation can be determined by distances between locations on the 3D, reconstructed shape and locations on the reference representation.

The use of a reference representation from an actual physical object that is similar to the desired model to programmatically generate an editable, 3D representation greatly improves the speed and efficiency of the 3D modeling process. The editable 3D representation will be complete even if the reference representation is missing data, for example, data for parts of the reference object that are not visible when the representation of the object is captured. Thus, no effort needs to be spent on filling in missing information, as instead of using the representation as is, a complete representation is selected and fitted to the reference representation, replacing a coarse, rough model with a more precise, complete model. Additional editing of the 3D model can be accomplished efficiently.

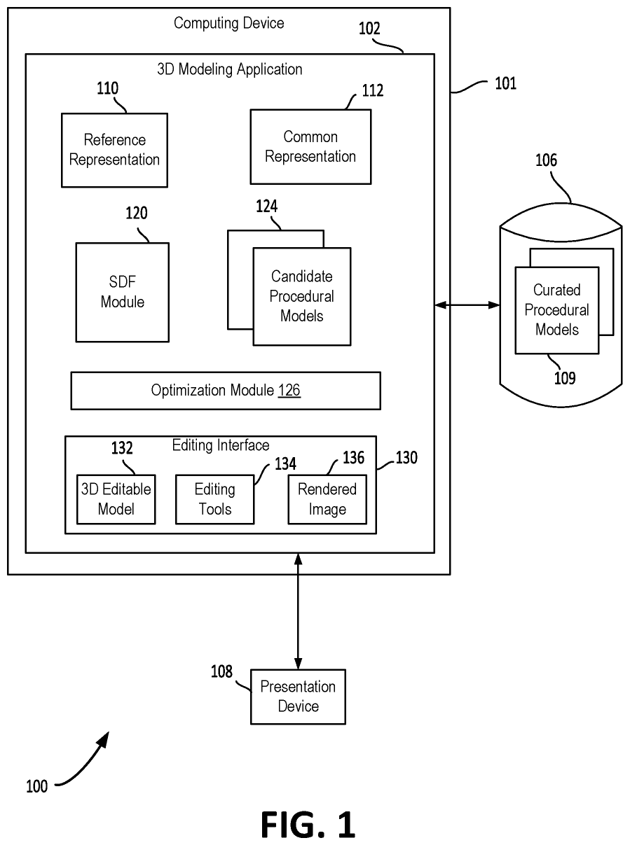

FIG. 1 is a diagram showing an example of a computing environment 100 for modeling shapes using differentiable, signed distance functions, according to certain embodiments. The computing environment 100 includes a computing device 101 that executes a 3D modeling application 102, a memory device 106 configured to store curated procedural models 109, and a presentation device 108 that is controlled based on the 3D modeling application 102. In this example, the 3D modeling application 102 includes the stored reference representation 110. The reference representation 110 can be used to produce common representation 112 of the object.

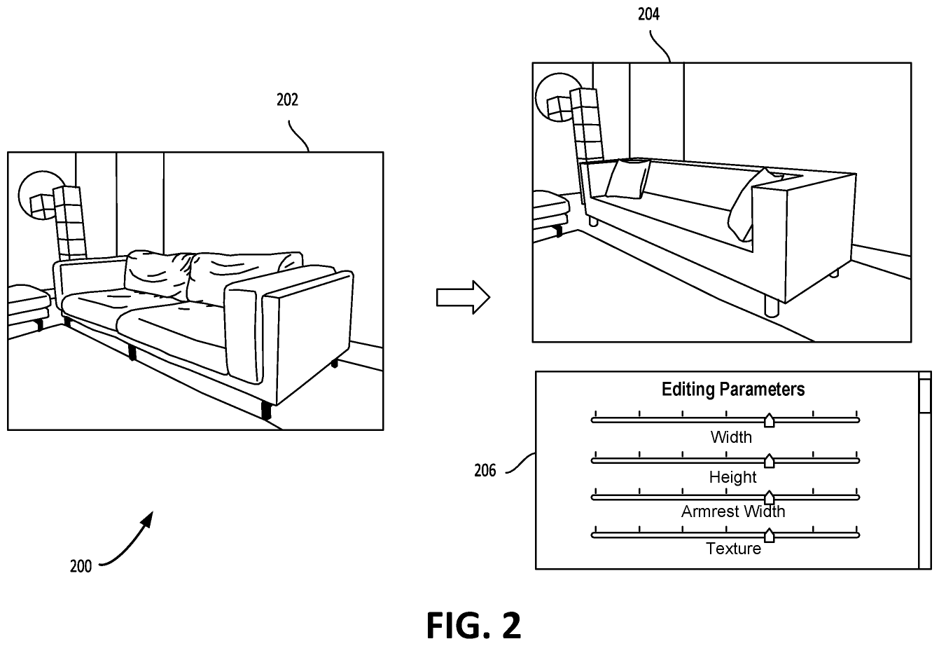

3D modeling application 102 can use common representation 112 to select candidate procedural models 124 from the library of curated procedural models 109. These candidate procedural models 124 are selected by sampling points associated with reference representation 110 and the point data stored as the common representation 112. The common representation is a set of 3D points for which a value of signed distance is assigned based on the reference representation. The common representation is thus a sampling of the SDF for the reference representation. Optimization module 126 optimizes each of the plurality of candidate procedural models by comparing a procedural value and a reference value (value based on the reference representation) of a differentiable SDF for each of the points associated with the reference representation of the object. SDF module 120 calculates the procedural and reference values and caches these values as needed. The resulting selected procedural model is an editable 3D procedural model 132, which can be edited in editing interface 130 using editing tools 134, further described below with respect to FIG. 2. The editing interface 130 can also be used to produce a rendered image 136 for viewing during editing or otherwise using presentation device 108. The rendered image is necessarily two-dimensional when a standard computing display is used as the presentation device.

FIG. 2 is an example 200 of a reference representation image and a corresponding rendered image based on a 3D, editable procedural model. In this example, the reference representation is based on LiDAR data captured using a LiDAR scanner directed to a physical sofa, and image 204 is a rendering of an editable 3D model that is programmatically created based on this representation. The LiDAR data is a cloud of individual points reflected from everything on any surface in the scene (including walls, woodwork, etc.), however, the sofa in this example is the object of interest. Some parts of the sofa are not visible to the scanner, resulting in LiDAR data that is incomplete with respect to the physical surfaces of the reference object. Nonetheless, the 3D modeling application 102 transforms the reference representation into a common representation by sampling the available points associated with the reference representation of the object and selecting candidate procedural models corresponding to the reference representation based on the common representation. Optimization is carried out to produce a selected, procedural model, which is used to produce the 3D, editable model, for which corresponding image 204 is rendered after editing input.

The stored model of the sofa corresponding to image 204 includes all surfaces, even those out of view, for which no data was available in the reference representation. The selected procedural model is based on differentiable SDFs. The selected 3D model has no artifacts. The 3D modeling application 102 can produce a complete model since the curated procedural models available for optimization are complete. The curated procedural models have high semantic value and can reasonably fit most objects of a given class with a minimal number of parameters. A selected procedural model can be morphed and adjusted automatically to fit the reference representation. Parts of the selected model that correspond to portions of the sofa not present in the original scan are inferred from the information embedded in the selected procedural model. The use of differential SDFs provides a model that can easily and efficiently be edited using straightforward editing tools such as those shown in window 206. During editing, parameter differences are propagated back to the 3D representation.

Continuing with FIG. 2, the output 3D model can be edited using editing interface 130, which includes parameters displayed in a window 206 associated with image 204. The adjustable parameters include many that correspond to the reconstructed shape as based on the reference representation, making them understandable without extensive knowledge of computer graphics technology. In this example, visible editing parameters include the width and height of the sofa itself, the armrest width, and the texture of the surface of the sofa. Window 206 is scrollable, and many parameters can be included, including those for color, specifics of the sofa's feet, accents such as pillows, number of cushions, etc. Examples of traditional 3D modeling parameters include rotation, translation, alignment, complexity triangulation quality, optimization point distribution, etc. Such traditional 3D modeling parameters can be included in those presented by the editing interface 130 of 3D modeling application 102. However, the editing parameters that correspond to the real world shape being modeled provide a more straightforward semantic that makes 3D modeling more readily available to those without extensive training or skill. These editing parameters are saved along with each curated procedural model and can be selected when each model is created to be made available to an end user of the system.

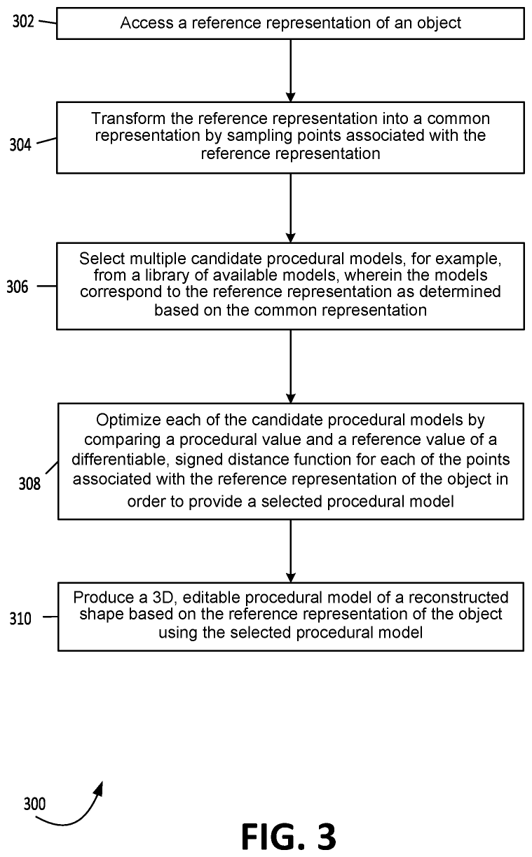

FIG. 3 is a flowchart of an example of a process 300 for modeling shapes using differentiable, signed distance functions, according to some embodiments. In this example, a computing device carries out the process by executing suitable program code, for example, computer program code executable to provide a 3D modeling application such as 3D modeling application 102. At block 302, the computing device accesses a reference representation of an object, for example, the sofa appearing in image 202. At block 304, the reference representation is transformed into a common representation by sampling points associated with the reference representation. For watertight 3D meshes, points within the space of the object are sampled. For a point cloud representation, such as a LiDAR scan, points outside and inside the shape are sampled. For voxel-based shapes, points on the shape and outside the shape are sampled.

Still referring to FIG. 3, at block 306, the computing device selects multiple candidate procedural models, for example, from a library of available procedural models such as the curated procedural models 109. At block 308, each of the candidate procedural models is optimized using optimization module 126 by comparing a procedural value and a reference value of a differentiable signed distance function for points associated with the reference representation of the object. The curated procedural models 109 can be stored on a network, or locally, in an independent database or as part of the 3D modeling application. The curated procedural models can be organized by class, for example, car models could be organized within a class termed, “vehicles” and may include subcategories such as “sedans,” “vans,” etc. As another example, procedural models of the sofa may be part of a class termed “furniture.”

To perform the optimization, procedural parameters for candidate procedural models are normalized. The reference values for the parameters of the candidate models can be used. Alternatively, a deep neural network can be used to determined improved initial reference values. The optimization loop proceeds by computing values of the candidate procedural SDF at the sample points in 3D space, measuring distances between the procedural and reference values, computing and minimizing the value of a loss function, and back-propagating the error in the loss to the parameters of the candidate procedural model. This optimization provides a selected procedural model that fits the common representation, and thus looks similar to the reference object. At block 310 of process 300, a 3D, editable procedural model of a reconstructed shape based on the reference representation is produced using the selected procedural model. An image of the shape can be rendered, for example, on presentation device 108. The model can be edited using editing tools 134.

To express the loss function for a given optimization as an equation, let P be the set of n 3D points that have been sampled around the reference object:

P={p₁,p₂, . . . , pₙ|∀i∈[1,n],pᵢ∈R³}.

The function h maps to a 3D point p, the value h(p) of the SDF of the reference object:

h:R³→R.

The above is the result of transforming the reference object into a common representation. Note that the function h is constant in the sense that it is not parameterized. Thus, it stays the same throughout the entire optimization. The function fₓ maps to a 3D point p; the value fₓ(p) of the SDF of the procedural model:

fₓ:R³→R.

The function fₓ is parameterized by a set of parameters x that are the parameters of the procedural model. The loss function L(x) measures how well the procedural model fits the reference object. Ideally, its value goes to zero after optimization, which would mean that the procedural model perfectly fits the reference object. The loss chosen in this example is the mean-squared error between two SDFs at points P:

L(x)=Σ_{p∈P}(fₓ(p)−h(p))².

The optimization problem to be solved is: x′=argminₓ L(x).

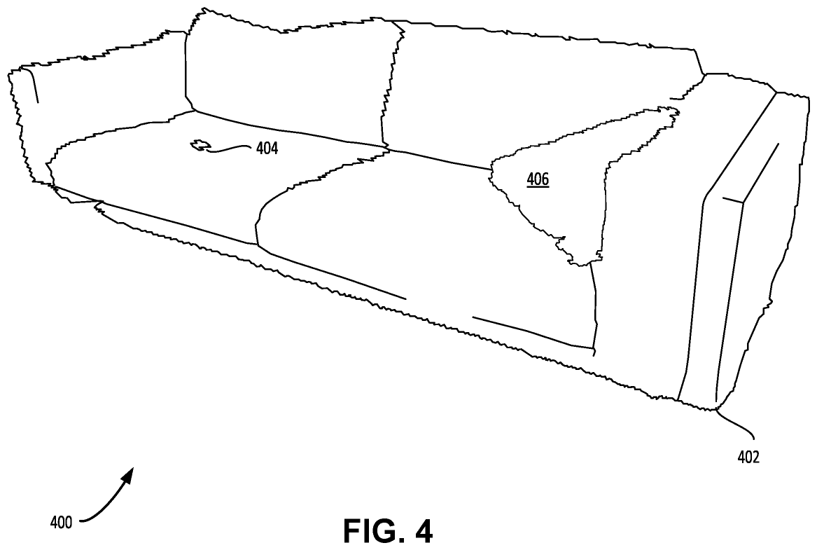

FIG. 4 is a reference representation 400 of the shape of the sofa illustrated in FIG. 2. The reference representation is based on the point cloud resulting from a LiDAR scan. Portions of the representation such as the outer arm 402 are fully represented. However, portion 404 is missing, probably because an indentation in the sofa prevented the LiDAR scanner from capturing a small area. Missing portion 406 is more extensive because the arm on the right created a shadow where the LiDAR scanner could not obtain data.

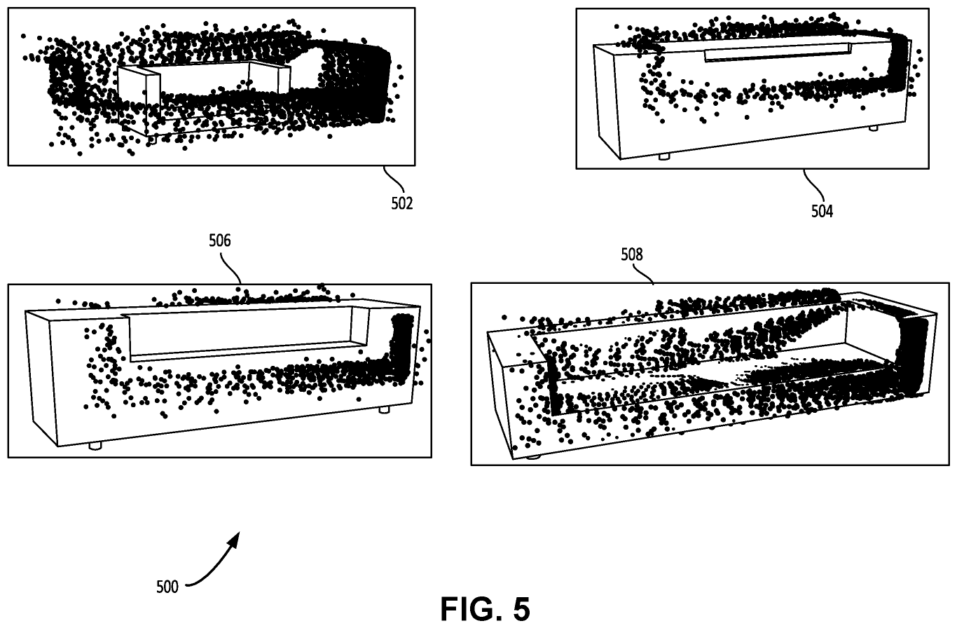

FIG. 5 is an example 500 of images depicting an optimization process including a candidate procedural model with various points being evaluated as parameters are varied to select a procedural model as part of modeling a shape using differentiable SDFs. Example 500 includes four images produced from a candidate procedural model. Image 502, image 504, image 506, and image 508 are each produced from a model that approximates the sofa, and each is optimized by comparing a procedural value and a reference value of the differentiable SDF for each of the points associated with the reference representation 110. The points pictured correspond to the surface of the reference object. In this example, points are sampled in 3D space from the point cloud of the reference representation. For example, if a LiDAR scan is used, these points would correspond to points in the LiDAR data as well as points around the LiDAR data. In each case, points outside the sofa shape are retained. The shape is optimized to the best fit of the point cloud from the reference representation, with procedural parameters being normalized between the respective bounds so that a parameter's range becomes zero to one. This normalization makes computation more efficient when optimization parameters have bounds that span many orders of magnitude.

While a point cloud representation can include points both inside and outside an object, the sofa's LiDAR point cloud is incomplete, resulting in uncertainty as to whether a 3D point is outside the sofa or not. This results in only points outside of the sofa being retained. If a complete scan of the sofa was available, 3D points inside the sofa could be confidently labeled.

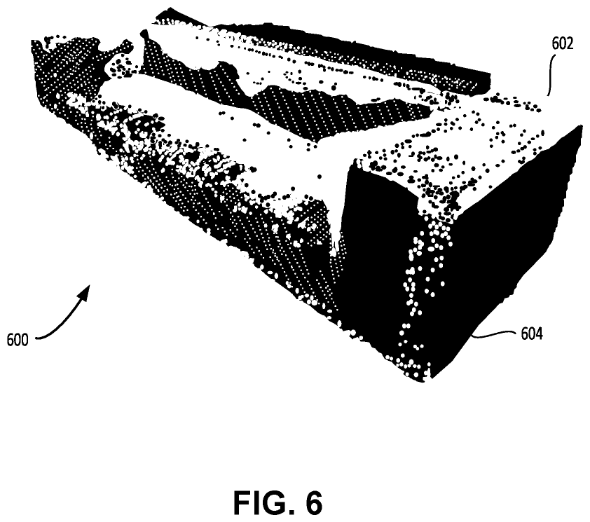

FIG. 6 is an example of a result of the optimization showing how a selected procedural model fits a reference object when modeling a shape using differentiable, signed distance functions, according to some embodiments. Image 600 depicts how well the procedural model fits the reference object in one example by showing one superimposed on the other. Unshaded areas 602 indicate points at the surface of the procedural model. The shaded areas 604 indicate points at the surface of the reference object.

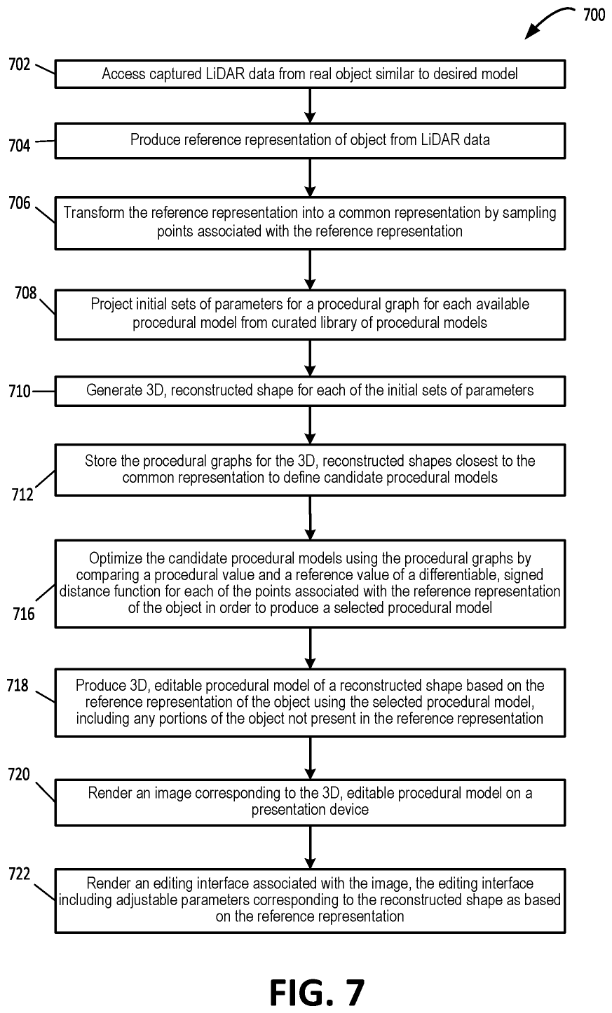

FIG. 7 is a flowchart of another example of a process 700 for modeling shapes using differentiable, signed distance functions, according to some embodiments. In this example, a computing device carries out the process by executing suitable program code, for example, computer program code executable to provide a 3D modeling application such as 3D modeling application 102. For purposes of this example, it can be assumed that the process begins with at least partial captured LiDAR data for a physical object of the type for which a 3D model is needed, for example, the sofa previously described.

At block 702, the computing device accesses captured LiDAR image data for the object of interest, the previously described sofa. At block 704, the LiDAR data is stored as the reference representation of the sofa. At block 706, the reference representation is transformed into a common representation by sampling points associated with the reference representation. In this example, points outside of the sofa are retained, as shown in FIG. 5. At block 708, the computing device accesses an initial set of parameters for a procedural graph for an available procedural model from the curated library of procedural models 109. The graph is a mathematical instruction for producing the model in three dimensions, whereas the model is what one would see if the physical object is created, or what defines what an image of the model would look like rendered in two dimensions on a display device.

At block 710 of FIG. 7, the computing device generates a 3D, reconstructed shape for each procedural graph from the curated library, each of which includes an initial set of parameters. At block 712, the procedural graphs are stored for the reconstructed shapes closest to the common representation in order to define multiple, candidate procedural models. The closest shape can be determined, as an example, by a minimum, mean signed distance between locations on the 3D, reconstructed shape and the reference representation or a minimum sum of signed distances between locations on the 3D, reconstructed shape and the reference representation. The functions included in block 708 through block 712 and discussed with respect to FIG. 7 can be used in implementing a step for selecting a plurality of candidate procedural models based on the common representation.

SDF module 120 represents 3D shapes using analytic SDFs as opposed to triangular meshes. The optimization module 126 leverages the mathematical properties of SDFs for the 3D shapes represented by the various procedural models. This technique allows the 3D procedural model that is output to be edited by manipulating a graph that is isolated from any specific rendering implementation because an SDF is analytically and/or procedurally defined. In one example, queries and commands are translated into an abstract syntax tree and then into a schema with data type handling. The procedural graphs are then defined based on the schema using a graph data definition language such as GLSL and the code is directly executed by a GPU. Graphs are stored and changed in a back-end database without altering or copying original data sources to storage used directly by the 3D editing application.

In one example, GLSL is used for rendering a procedural model in the modeling application. The SDF space is sampled and then the error from the loss function is back-propagated to the graph parameters to obtain partial derivatives of the graph parameters and make available a gradient of the SDF at any point. All of these operations can be executed efficiently on a typical GPU. The use of differentiable SDFs provides a processing-efficient way to morph or modify a detailed, pre-existing shape to a rough representation of an object that is close to the object that is ultimately desired. In this example, the database is accessed to select a set of candidate procedural models 124. The API for this database can be customized so that a machine-learning model can implement at least portions of the optimization module 126. A multidimensional array is used to store the input, the hidden layer representations, and the output.

Continuing with FIG. 7, at block 716, each of the candidate procedural models is optimized by comparing procedural values and a reference value of a differentiable SDF for points associated with the reference representation of the object, as just described, using the procedural graphs corresponding to the candidate procedural models. The candidate procedural model with the smallest difference between the values is selected, and becomes the selected procedural model for the modeling project. The closest candidate procedural model can be determined by the differences between the reference value and procedural value at each point that is compared.

To optimize the point cloud of the sofa used as an example, points are sampled in 3D space, and the distance of each to the corresponding point in 3D point cloud of the reference, scanned sofa is computed. In this example, only points outside the sofa are kept. The shape is optimized to the best fit for the point cloud using the mean-square-error loss function. During optimization, procedural parameters are normalized between the respective bounds as previously discussed with respect to FIG. 5, in order to ease optimization for bounds that span many orders of magnitude. Discontinuous functions in a graph, such as min, max, floor, etc., are translated into smooth versions using the back-end database so that the gradient can be back-propagated.

At block 718, the computing device produces the 3D, editable procedural model of the reconstructed shape based on the reference representation of the object using the selected procedural model. The computing device inherently infers portions of the desired object that were not present in the reference representation. The selected procedural model includes these portions of the object because the candidate procedural models are complete. These portions are not present in the reference representation because they were not captured by the LiDAR scan. For example, the images of the sofa as previously described do not include images of the back of the sofa, but these portions are present in the procedural model because the procedural graphs from the database are complete. The functions included in block 716 through block 718 and discussed with respect to FIG. 7 can be used in implementing a step for producing a 3D, editable procedural model of a reconstructed shape. At block 720, an image corresponding to the 3D editable procedural model is displayed on presentation device 108. At block 722, the editing interface is rendered as associated with the image. The editing interface includes adjustable parameters corresponding to the reconstructed shape as based on the type of object in the reference representation.

The 3D, editable procedural model is edited by working with a stored graph as described above, and changes are reflected back into the image of the object displayed in editing interface 130. The adjustable parameters that are specific to the type of object being designed may be presented exclusively, or along with, traditional graphics editing parameters. In one example, 3D editing application 102 displays a menu setting that provides for selection of an “easy” editing mode or an “expert” editing mode and the expert mode causes the computing device to include traditional 3D modeling parameters in the editing interface 130.

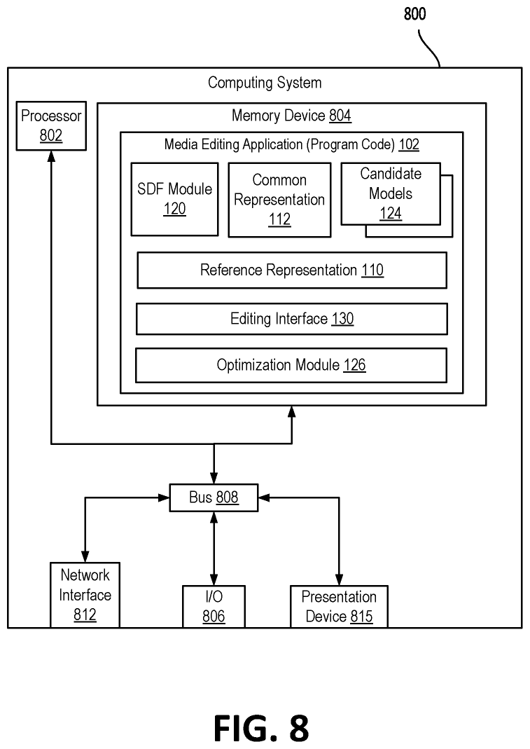

FIG. 8 is a diagram of an example of a computing system 800 that can implement aspects of modeling shapes using differentiable, signed distance functions, according to certain embodiments. System 800 includes a processor 802 communicatively coupled to one or more memory devices 804. The processor 802 executes computer-executable program code stored in the memory device 804. Examples of the processor 802 include a microprocessor, an application-specific integrated circuit (“ASIC”), a field-programmable gate array (“FPGA”), or any other suitable processing device. The processor 802 can include any number of processing devices, including a single processing device. The memory device 804 includes any suitable non-transitory computer-readable medium for storing data, program code, or both. A computer-readable medium can include any electronic, optical, magnetic, or other storage device capable of providing a processor with computer-readable instructions or other program code. Non-limiting examples of a computer-readable medium include a magnetic disk, a memory chip, a ROM, a RAM, an ASIC, optical storage, magnetic tape or other magnetic storage, or any other medium from which a processing device can read instructions. The instructions may include processor-specific instructions generated by a compiler or an interpreter from code written in any suitable computer-programming language, including, for example, C, C++, C#, Visual Basic, Java, Python, Perl, JavaScript, and ActionScript.

Still referring to FIG. 8, the computing system 800 may also include a number of external or internal devices, for example, input or output devices. For example, the computing system 800 is shown with one or more input/output (“I/O”) interfaces 806. An I/O interface 806 can receive input from input devices or provide output to output devices (not shown). One or more buses 808 are also included in the computing system 800. The bus 808 communicatively couples one or more components of a respective one of the computing system 800. The processor 802 executes program code that configures the computing system 800 to perform one or more of the operations described herein. The program code includes, for example, 3D editing application 102, or other suitable applications that perform one or more operations described herein. The program code may be resident in the memory device 804 or any suitable computer-readable medium and may be executed by the processor 802 or any other suitable processor. Memory device 804, during operation of the computing system, executable portions of the 3D editing application, for example, SDF module 120 and/or optimization module 126, and editing interface 130 can access portions as needed. Memory device 804 is also used to temporarily store candidate models 124, and representations 110 and 112, as well as other information or data structures, shown or not shown in FIG. 8, as needed.

The system 800 of FIG. 8 also includes a network interface device 812. The network interface device 812 includes any device or group of devices suitable for establishing a wired or wireless data connection to one or more data networks. Non-limiting examples of the network interface device 812 include an Ethernet network adapter, a wireless network adapter, and/or the like. The system 800 is able to communicate with one or more other computing devices (e.g., another computing device executing other software, not shown) via a data network (not shown) using the network interface device 812. Network interface device 812 can also be used to communicate with network or cloud storage used as a repository for curated procedural models 109 for use with the 3D editing application 102. Such network or cloud storage can also include updated or archived versions of the 3D editing application for distribution and installation.

Staying with FIG. 8, in some embodiments, the computing system 800 also includes the presentation device 815 depicted in FIG. 8. A presentation device 815 can include any device or group of devices suitable for providing visual, auditory, or other suitable sensory output. In examples, presentation device 815 displays images of 3D objects being edited. Non-limiting examples of the presentation device 815 include a touchscreen, a monitor, a separate mobile computing device, etc. In some aspects, the presentation device 815 can include a remote client-computing device that communicates with the computing system 800 using one or more data networks. System 800 may be implemented as a unitary computing device, for example, a notebook or mobile computer. Alternatively, as an example, the various devices included in system 800 may be distributed and interconnected by interfaces or a network, with a central or main computing device including one or more processors.

Numerous specific details are set forth herein to provide a thorough understanding of the claimed subject matter. However, those skilled in the art will understand that the claimed subject matter may be practiced without these specific details. In other instances, methods, apparatuses, or systems that would be known by one of ordinary skill have not been described in detail so as not to obscure claimed subject matter.

Unless specifically stated otherwise, it is appreciated that throughout this specification discussions utilizing terms such as “accessing,” “selecting,” “processing,” “computing,” and “determining” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provide a result conditioned on one or more inputs. Suitable computing devices include multi-purpose microprocessor-based computer systems accessing stored software that programs or configures the computing system from a general purpose computing apparatus to a specialized computing apparatus implementing one or more implementations of the present subject matter. Any suitable programming, scripting, or other type of language or combinations of languages may be used to implement the teachings contained herein in software to be used in programming or configuring a computing device.

Embodiments of the methods disclosed herein may be performed in the operation of such computing devices. The order of the blocks presented in the examples above can be varied—for example, blocks can be re-ordered, combined, and/or broken into sub-blocks. Certain blocks or processes can be performed in parallel.

The use of “configured to” herein is meant as open and inclusive language that does not foreclose devices adapted to or configured to perform additional tasks or steps. Headings, lists, and numbering included herein are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations, and/or additions to the present subject matter as would be readily apparent to one of ordinary skill in the art.

What is claimed is:

1. A method comprising:
accessing a reference representation of an object;
transforming the reference representation into a common representation by sampling points associated with the reference representation of the object;
selecting a plurality of candidate procedural models corresponding to the reference representation based on the common representation;
optimizing the plurality of candidate procedural models by comparing a procedural value and a reference value of a differentiable signed distance function for each of the points associated with the reference representation of the object to provide a selected procedural model; and
producing a 3D, editable procedural model of a reconstructed shape based on the reference representation of the object using the selected procedural model.

2. The method of claim 1, wherein selecting the plurality of candidate procedural models further comprises:
accessing a set of initial parameters for a procedural graph for each available procedural model;
generating a 3D, reconstructed shape for each set of initial parameters; and
storing the procedural graph for the 3D, reconstructed shape closest to the common representation.

3. The method of claim 2, further comprising determining the 3D, reconstructed shape closest to the reference representation by minimizing a mean-squared error of signed distances between locations on the 3D, reconstructed shape and the reference representation.

4. The method of claim 2, further comprising determining the 3D, reconstructed shape closest to the reference representation by minimizing a value of a loss function.

5. The method of claim 1, further comprising:
rendering an image corresponding to the 3D, editable procedural model; and
rendering an editing interface associated with the image, the editing interface including adjustable parameters corresponding to the reconstructed shape as based on the reference representation.

6. The method of claim 1, further comprising accessing partial captured LiDAR image data from the object to produce the reference representation.

7. The method of claim 1, wherein the selected procedural model includes portions of the object not present in the reference representation.

8. A system comprising:
a memory component; and
a processing device coupled to the memory component, the processing device to perform operations comprising:
transforming a reference representation of an object into a common representation by sampling points associated with the reference representation of the object;
selecting a plurality of candidate procedural models corresponding to the reference representation based on the common representation;
optimizing the plurality of candidate procedural models by comparing a procedural value and a reference value of a differentiable signed distance function for each of the points associated with the reference representation of the object to provide a selected procedural model;
producing a 3D, editable procedural model of a reconstructed shape based on the reference representation of the object using the selected procedural model;
rendering an image corresponding to the 3D, editable procedural model; and
rendering an editing interface associated with the image.

9. The system of claim 8, wherein the operation of selecting the plurality of candidate procedural models further comprises the operations of:
accessing a set of initial parameters for a procedural graph for each available procedural model;
generating a 3D, reconstructed shape for each set of initial parameters; and
storing the procedural graph for the 3D, reconstructed shape closest to the common representation.

10. The system of claim 9, wherein the operations further comprise determining the 3D, reconstructed shape closest to the reference representation by minimizing a mean-squared error in signed distances between locations on the 3D, reconstructed shape and the reference representation.

11. The system of claim 9, wherein the operations further comprise determining the 3D, reconstructed shape closest to the reference representation by minimizing a value of a loss function.

12. The system of claim 8, wherein the editing interface comprises adjustable parameters corresponding to the reconstructed shape as based on the reference representation.

13. The system of claim 8, wherein the operations further comprise accessing partial captured LiDAR image data from the object to produce the reference representation.

14. The system of claim 8, wherein the selected procedural model includes portions of the object not present in the reference representation.

15. A non-transitory computer-readable medium storing executable instructions, which when executed by a processing device, cause the processing device to perform operations comprising:
accessing a reference representation of an object;
transforming the reference representation into a common representation by sampling points associated with the reference representation of the object;
a step for selecting a plurality of candidate procedural models based on the common representation; and
a step for producing a 3D, editable procedural model of a reconstructed shape based on the reference representation of the object using a selected procedural model.

16. The non-transitory computer-readable medium of claim 15, wherein the operations further comprise determining a 3D, reconstructed shape closest to the reference representation by minimizing a mean-squared error in signed distances between locations on the 3D, reconstructed shape and the reference representation.

17. The non-transitory computer-readable medium of claim 15, wherein the operations further comprise determining the 3D, reconstructed shape closest to the reference representation by minimizing a value of a loss function.

18. The non-transitory computer-readable medium of claim 15, wherein the operations further comprise rendering an editing interface including adjustable parameters corresponding to the reconstructed shape as based on the reference representation.

19. The non-transitory computer-readable medium of claim 15, wherein the operations further comprise accessing partial captured LiDAR image data from the object to produce the reference representation.

20. The non-transitory computer-readable medium of claim 15, wherein the selected procedural model includes portions of the object not present in the reference representation.
